(19) United States
(12) Patent Application Publication
(10) Pub. No.: US 2026/0056362 A1
(43) Pub. Date: Feb. 26, 2026

(54) LIGHT RECEIVING ELEMENT AND METHOD OF MANUFACTURING LIGHT RECEIVING ELEMENT

(71) Applicant: SUMITOMO ELECTRIC INDUSTRIES, LTD., Osaka-shi (JP)

(72) Inventor: Takuya OKIMOTO, Osaka-shi (JP)

(73) Assignee: SUMITOMO ELECTRIC INDUSTRIES, LTD., Osaka-shi (JP)

(21) Appl. No.: 19/305,111

(22) Filed: Aug. 20, 2025

(30) Foreign Application Priority Data
Aug. 23, 2024 (JP) 2024-143252

(51) Int. Cl. G02B 6/122; G02B 6/12; H10F 30/223; H10F 71/00; H10F 77/124; H10F 77/40

(52) U.S. Cl. CPC G02B 6/1228; H10F 30/223; H10F 71/1272; H10F 77/1248; H10F 77/413; G02B 2006/12061; G02B 2006/12123

(57) ABSTRACT

A light receiving element is used to receive an optical signal. The light receiving element includes a substrate having a silicon layer, and a photodiode formed of a III-V compound semiconductor and bonded to the silicon layer. The silicon layer includes a waveguide, a recess, an air gap, and a wall, the wall is provided between the recess and the air gap, the waveguide is connected to the wall, the waveguide and the recess are provided outside the photodiode, and the air gap is provided at a position overlapping the photodiode. The substrate includes a silicon substrate and a silicon oxide layer. The photodiode includes a light-absorbing layer.

### CROSS REFERENCE TO RELATED APPLICATIONS

This application claims priority based on Japanese Patent Application No. 2024-143252 filed on Aug. 23, 2024, and the entire contents of the Japanese patent application are incorporated herein by reference.

### TECHNICAL FIELD

The present disclosure relates to a light receiving element and a method of manufacturing a light receiving element.

### BACKGROUND

By bonding a photodiode formed of a III-V compound semiconductor to a substrate such as a silicon on insulator (SOI) substrate that has a waveguide formed (silicon photonics), a hybrid type light receiving element can be formed (for example, Non-patent literature 1: Ye Wang, et al. “High-Power Photodiodes With 65 GHz Bandwidth Heterogeneously Integrated Onto Silicon-on-Insulator Nano-Waveguides” IEEE Journal of Selected Topics in Quantum Electronics, Vol. 24, No. 2, 6000206, March/April 2018).

### SUMMARY

A light receiving element according to the present disclosure includes a substrate having a silicon layer, and a photodiode formed of a III-V compound semiconductor and bonded to the silicon layer. The silicon layer includes a waveguide, a recess, an air gap, and a wall, the wall is provided between the recess and the air gap, the waveguide is connected to the wall, the waveguide and the recess are provided outside the photodiode, and the air gap is provided at a position overlapping the photodiode.

### BRIEF DESCRIPTION OF THE DRAWINGS

FIG. 1A is a top view illustrating a light receiving element according to a first embodiment.

FIG. 1B is a perspective view illustrating a light receiving element.

FIG. 2A is a cross-sectional view illustrating a light receiving element.

FIG. 2B is a cross-sectional view illustrating a light receiving element.

FIG. 3A is a top view illustrating parameters in a simulation.

FIG. 3B is a map illustrating the results of a simulation.

FIG. 3C is a map illustrating the results of a simulation.

FIG. 4A is a top view illustrating a method of manufacturing a light receiving element.

FIG. 4B is a perspective view illustrating a method of manufacturing a light receiving element.

FIG. 5A is a top view illustrating a method of manufacturing a light receiving element.

FIG. 5B is a perspective view illustrating a method of manufacturing a light receiving element.

FIG. 6A is a top view illustrating a method of manufacturing a light receiving element.

FIG. 6B is a perspective view illustrating a method of manufacturing a light receiving element.

FIG. 7A is a top view illustrating a method of manufacturing a light receiving element.

FIG. 7B is a perspective view illustrating a method of manufacturing a light receiving element.

FIG. 8A is a top view illustrating a method of manufacturing a light receiving element.

FIG. 8B is a perspective view illustrating a method of manufacturing a light receiving element.

FIG. 9 is a plan view illustrating a light receiving element according to a second embodiment.

FIG. 10A is a top view illustrating a light receiving element according to a third embodiment.

FIG. 10B is a diagram illustrating a responsivity.

FIG. 11A is a perspective view illustrating a light receiving element according to a fourth embodiment.

FIG. 11B is a perspective view illustrating a substrate.

FIG. 12 is a diagram illustrating calculation results of responsivity and a quantum efficiency.

FIG. 13A is a top view illustrating parameters in a simulation.

FIG. 13B is a map illustrating the results of a simulation.

FIG. 13C is a map illustrating the results of a simulation.

FIG. 14A is a map illustrating the results of a simulation.

FIG. 14B is a map illustrating the results of a simulation.

### DETAILED DESCRIPTION

In order to expand the operating bandwidth, the photodiode may be miniaturized. In order to obtain high responsivity even with a small photodiode, the coupling efficiency to the photodiode is increased. By forming a portion of the substrate overlapping with the photodiode to have an air cladding structure, it is possible to strengthen the light confinement in the photodiode and increase the responsivity. However, there is a possibility that the chemical solution intrudes into the air cladding and damages the photodiode. Thus, an object of the present disclosure is to provide a light receiving element having high responsivity and being less likely to be damaged, and a method of manufacturing the light receiving element.

### [Description of Embodiments of Present Disclosure]

First, the contents of the embodiments of the present disclosure will be listed and described.

(1) A light receiving element according to an aspect of the present disclosure includes a substrate having a silicon layer, and a photodiode formed of a III-V compound semiconductor and bonded to the silicon layer. The silicon layer includes a waveguide, a recess, an air gap, and a wall, the wall is provided between the recess and the air gap, the waveguide is connected to the wall, the waveguide and the recess are provided outside the photodiode, and the air gap is provided at a position overlapping the photodiode. Since the air gap functions as an air cladding, it is possible to strengthen the light confinement in the photodiode and increase the responsivity. By miniaturizing the photodiode, high-speed operation is possible. The wall is disposed between the recess and the air gap to block the chemical solution or the like. Since the etchant does not enter the air gap, damage to the photodiode is less likely to occur.

(2) In the above (1), the silicon layer may include a first tapered portion, a width of the first tapered portion may be larger closer to the photodiode and smaller farther from the photodiode, and the waveguide may be connected to the first tapered portion. Loss of light can be reduced and the responsivity can be increased.

(3) In the above (2), the first tapered portion may be disposed between the wall and the waveguide, and may be connected to the wall and the waveguide. Loss of light can be reduced and the responsivity can be increased.

(4) In any one of the above (1) to (3), the silicon layer may have a second tapered portion, the second tapered portion may be connected to the wall and may overlap the photodiode, and a width of the second tapered portion may be larger closer to the wall and smaller farther from the wall. Loss of light can be reduced and the responsivity can be increased.

(5) In the above (2), the wall may include the first tapered portion. Loss of light can be reduced and the responsivity can be increased.

(6) In any one of the above (1) to (5), the silicon layer may have a first slab portion, the photodiode may be bonded to the first slab portion, the wall may be connected to the first slab portion, and the air gap may be surrounded by the wall and the first slab portion. Since the chemical solution or the like does not intrude into the air gap, damage to the photodiode is less likely to occur.

(7) In any one of the above (1) to (6), the photodiode may include a first semiconductor layer, a light-absorbing layer, and a second semiconductor layer, the first semiconductor layer may have a first conductivity type, the second semiconductor layer may have a second conductivity type, the first semiconductor layer may be bonded to the silicon layer, the light-absorbing layer and the second semiconductor layer may be stacked on the first semiconductor layer in this order to form a mesa, and the air gap may be provided at a position overlapping the mesa. Since the air gap functions as an air cladding, light can be confined in the mesa. By efficiently coupling light into the light-absorbing layer, the responsivity can be increased.

(8) In the above (7), the first semiconductor layer may include a second slab portion and a protruding portion, the protruding portion may be connected to the second slab portion and may protrude from the second slab portion toward the waveguide, the mesa may protrude from the second slab portion in a direction opposite to the silicon layer, and the air gap may be provided at a position overlapping the mesa and the second slab portion. The coupling efficiency can be increased and the responsivity can be increased.

(9) In the above (8), the mesa may extend from a position overlapping the second slab portion to a position overlapping the protruding portion. Light is absorbed in the mesa before reaching the wall. Loss of light due to the wall can be reduced and the responsivity can be increased.

(10) In any one of the above (7) to (9), the mesa may have a third tapered portion, and the third tapered portion may have a shape tapering along an extending direction of the waveguide. The coupling efficiency is increased, and the responsivity can be further increased.

(11) In any one of the above (7) to (10), a portion of the mesa may overlap the silicon layer and may be supported by the silicon layer. The mechanical strength is improved.

(12) A method of manufacturing a light receiving element is a method of manufacturing a light receiving element including a substrate having a silicon layer, and a photodiode formed of a III-V compound semiconductor. The silicon layer includes a waveguide, a recess, an air gap, and a wall, the wall is provided between the recess and the air gap, and the waveguide is connected to the wall. The method includes bonding the photodiode to the silicon layer, and performing a wet etching on the photodiode. After the performing of the wet etching, the waveguide and the recess are provided outside the photodiode, and the air gap is provided at a position overlapping the photodiode. Since the air gap functions as an air cladding, it is possible to strengthen the light confinement in the photodiode. The responsivity can be increased. By miniaturizing the photodiode, high-speed operation is possible. The wall is disposed between the recess and the air gap to block the chemical solution or the like. Since the etchant does not enter the air gap, damage to the photodiode is less likely to occur.

### [Details of Embodiments of Present Disclosure]

Specific examples of a light receiving element and a method of manufacturing a light receiving element according to an embodiment of the present disclosure will be described below with reference to the drawings. The present disclosure is not limited to these illustrative examples, but is defined by the appended claims, and is intended to include all modifications within the scope and meaning equivalent to the appended claims.

### First Embodiment

### (Light Receiving Element)

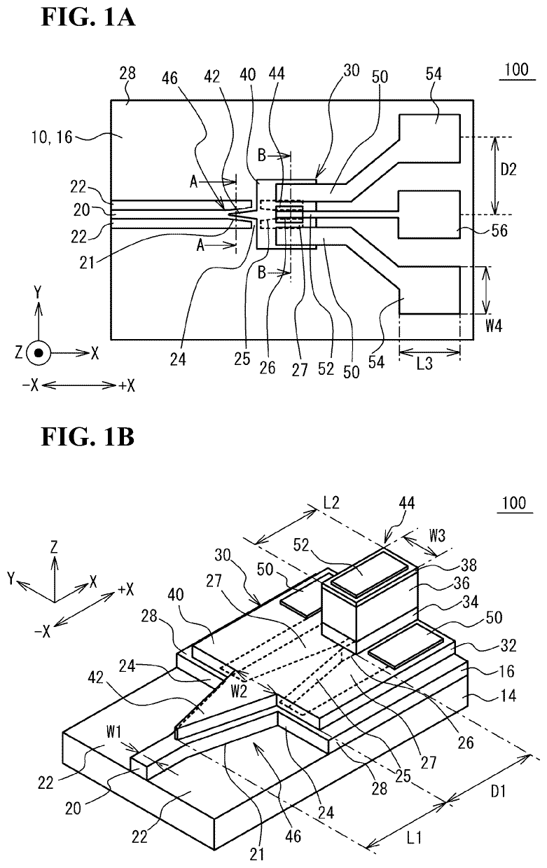

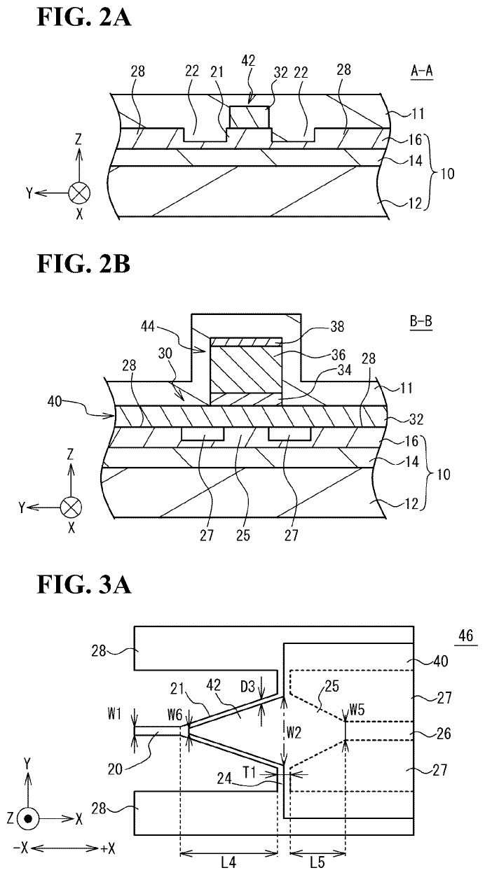

FIG. 1A is a top view illustrating a light receiving element 100 according to a first embodiment. FIG. 1B is a perspective view illustrating the light receiving element 100. FIGS. 2A and 2B are cross-sectional views each illustrating the light receiving element 100. FIG. 2A shows a cross-section along line A-A of FIG. 1A. FIG. 2B shows a cross-section along line B-B of FIG. 1A. In the perspective view, a substrate 12 of a substrate 10 is omitted.

As shown in FIG. 1A and FIG. 1B, the light receiving element 100 is a hybrid type light receiving element, and has the substrate 10, a photodiode 30, and a transition structure 46. In the transition structure 46, the light is coupled from the substrate 10 to the photodiode 30. The photodiode 30 is bonded to the upper surface of the substrate 10, absorbs light, and outputs an electrical signal. A Z-axis direction is the normal direction of the upper surface of the substrate 10. An X-axis direction is a direction parallel to the waveguide. A Y-axis direction is orthogonal to the X-axis direction and the Z-axis direction. One direction along the X axis is taken as the negative X-axis direction and the other direction is taken as the positive X-axis direction.

### (Substrate)

As shown in FIG. 2A and FIG. 2B, the substrate 10 is an SOI (Silicon on Insulator) substrate, and has the substrate 12, a BOX (Buried Oxide) layer 14, and a silicon layer 16. The substrate 12, the BOX layer 14, and the silicon layer 16 are stacked in order in the Z-axis direction. The substrate 12 is formed of, for example, silicon (Si). The BOX layer 14 is formed of, for example, silicon oxide (SiO₂). The thickness of the BOX layer 14 is, for example, 3 μm. The thickness of the silicon layer 16 is, for example, 220 nm. The upper surface of the substrate 10 and the surface of the photodiode 30 are covered with an insulation film 11. The insulation film 11 is formed of, for example, SiO₂ having a thickness of 1 μm. The refractive index of the silicon layer 16 is 3.45. The refractive index of the BOX layer 14 and the insulation film 11 is 1.45, which is lower than that of the silicon layer 16. These refractive indices are values for light having a wavelength of 1.55 μm. A waveguide and the like are provided in the silicon layer 16.

As shown in FIG. 1A and FIG. 1B, the substrate 10 has a waveguide 20, a tapered portion 21 (first tapered portion), a recess 22, a wall 24, a tapered portion 25 (second tapered portion), a waveguide 26, an air gap 27, and a slab portion 28 (first slab portion). The slab portion 28 is a planar portion of the silicon layer 16 and is parallel to the XY plan.

In the X-axis direction, the waveguide 20, the tapered portion 21, the wall 24, the tapered portion 25, and the waveguide 26 are arranged in this order. The tapered portion 21 is disposed between the waveguide 20 and the wall 24 and is connected to the waveguide 20 and the wall 24. The width of the tapered portion 21 is larger closer to the wall 24, and is smaller farther from the wall 24. The tapered portion 25 is disposed between the wall 24 and the waveguide 26 and is connected to the wall 24 and the waveguide 26. The width of the tapered portion 25 is larger closer to the wall 24 and is smaller farther from the wall 24.

The waveguide 20 and the waveguide 26 are parallel to the X-axis direction. The waveguide 20 is connected to the distal end of the tapered portion 21. The recesses 22 are grooves, which extend parallel to the X-axis direction and are disposed on both sides of the waveguide 20 and the tapered portion 21 in the Y-axis direction. The waveguide 20 and the recess 22 extend from the wall 24 to an end portion of the substrate 10 in the negative X direction. A width W1 of the waveguide 20 is, for example, 0.3 μm to 0.6 μm.

The waveguide 26 is connected to the distal end of the tapered portion 25. The waveguide 26 does not reach the end portion of the substrate 10 in the positive X direction, and extends to the partway of the substrate 10. The air gap 27 is disposed on both sides of the waveguide 26 and the tapered portion 25 in the Y-axis direction.

The wall 24 extends in the Y-axis direction and is perpendicular to the X-axis direction. The wall 24 is connected to the slab portion 28, and is disposed between the recess 22 and the air gap 27 to separate the recess 22 and the air gap 27. The recess 22 is disposed in the negative X direction with respect to the wall 24, and the air gap 27 is disposed in the positive X direction with respect to the wall 24.

The upper surfaces of the waveguide 20, the tapered portion 21, the wall 24, the tapered portion 25, the waveguide 26, and the slab portion 28 are disposed at the same height in the Z-axis direction, and protrude more than the recess 22 and the air gap 27. The recess 22 and the air gap 27 are recessed in the Z-axis direction as compared with the slab portion 28 and the like. The recess 22 and the air gap 27 may penetrate the silicon layer 16 or may extend to the partway of the silicon layer 16. The insulation film 11 is embedded in the recess 22. The air gap 27 is hollow and is filled with air.

### (Photodiode)

The photodiode 30 is a semiconductor element formed of a III-V compound semiconductor. The photodiode 30 is bonded to the silicon layer 16. As shown in FIG. 1B and FIG. 2B, the photodiode 30 has a semiconductor layer 32 (first semiconductor layer), a light-absorbing layer 34, a semiconductor layer 36 (second semiconductor layer), and a contact layer 38 (second semiconductor layer). The semiconductor layer 32 is in contact with the silicon layer 16 of the substrate 10. On the surface of the semiconductor layer 32 opposite to the substrate 10, the light-absorbing layer 34, the semiconductor layer 36, and the contact layer 38 are stacked in this order.

The semiconductor layer 32 is formed of, for example, n-type (first conductivity type) indium phosphide (n-InP). The semiconductor layer 32 is doped with, for example, silicon (Si). The thickness of the semiconductor layer 32 is, for example, 400 nm. The light-absorbing layer 34 is formed of, for example, undoped indium gallium arsenide (InGaAs). The light-absorbing layer 34 may be formed of only bulk InGaAs. The thickness of the light-absorbing layer 34 is, for example, 400 nm. The semiconductor layer 36 is formed of, for example, p-type (second conductivity type) indium phosphide (p-InP). The thickness of the semiconductor layer 36 is, for example, 1300 nm. The contact layer 38 is formed of, for example, p⁺ type indium gallium arsenide ((p⁺)-InGaAs). The thickness of the contact layer 38 is, for example, 300 nm. The semiconductor layer 36 and the contact layer 38 are doped with, for example, zinc (Zn). The semiconductor layers of the photodiode 30 may be formed of a III-V compound semiconductor other than the above.

As shown in FIG. 1A and FIG. 1B, the photodiode 30 has a slab portion 40 (second slab portion), a protruding portion 42, and a mesa 44. As shown in FIG. 1B, the semiconductor layer 32 has the slab portion 40 and the protruding portion 42. The mesa 44 includes the light-absorbing layer 34, the semiconductor layer 36, and the contact layer 38. As shown in FIG. 2A, the protruding portion 42 is covered with the insulation film 11. As shown in FIG. 2B, the slab portion 40 and the mesa 44 are also covered with the insulation film 11.

As shown in FIG. 1A and FIG. 1B, the slab portion 40 is planar and is provided over a wider area than the mesa 44, and is bonded to the slab portion 28 of the silicon layer 16. The width of the slab portion 40 is larger than the width of the protruding portion 42.

The protruding portion 42 is connected to an end portion of the slab portion 40 in the negative X direction and protrudes from the end portion to a position overlapping the tapered portion 21 of the silicon layer 16. The entire protruding portion 42 is a tapered portion, and has a shape tapering along the negative X-axis direction.

The distal end of the protruding portion 42 has, for example, a curved shape. The protruding portion 42 is, for example, line symmetric with respect to the X-axis direction.

The width of the protruding portion 42 is larger closer to the slab portion 40, and is smaller farther from the slab portion 40. A width W2 of the portion of the protruding portion 42 connected to the slab portion 40 is, for example, 1 μm to 10 μm. A length L1 of the protruding portion 42 in the X-axis direction is, for example, 2 μm to 100 μm.

The mesa 44 is disposed on the slab portion 40, protrudes from the slab portion 40 in the Z-axis direction, and faces the protruding portion 42 in the X-axis direction. The shape of the mesa 44 is, for example, a rectangular parallelepiped. A length L2 of the mesa 44 in the X-axis direction shown in FIG. 1B is, for example, 5 μm to 20 μm. A width W3 of the mesa 44 in the Y-axis direction is, for example, 0.5 μm to 6 μm, and is 2 μm as an example. A distance D1 from the distal end of the mesa 44 in the negative X direction to the distal end of the slab portion 40 in the negative X direction is, for example, 20 μm or less.

The tapered portion 21 of the silicon layer 16 overlaps the protruding portion 42 of the photodiode 30 in the Z-axis direction. The wall 24 and the tapered portion 25 overlap the slab portion 40. The waveguide 26 and the air gap 27 overlap the slab portion 40 and the mesa 44. The waveguide 26 extends to an end portion of the mesa 44 in the positive X direction. The width of the tapered portion 21 is larger closer to the mesa 44 of the photodiode 30 and is smaller farther from the mesa 44.

The transition structure 46 includes the tapered portion 21 and the tapered portion 25 of the silicon layer 16, and the protruding portion 42 of the photodiode 30. The transition structure 46 has a kite shape in the plan view.

As shown in FIG. 1A, the light receiving element 100 has an electrode 50, an electrode 52, a pad 54, and a pad 56. The electrode and the pad are formed of metal. The two electrodes 50 are cathodes and are electrically connected to the semiconductor layer 32. The pad 54 is electrically connected to the electrode 50. The electrode 52 is an anode and is electrically connected to the contact layer 38. The pad 56 is electrically connected to the electrode 52.

A length L3 of the pad 54 in the X-axis direction is, for example, 50 μm to 150 μm. A width W4 of the pad 54 in the Y-axis direction is, for example, 50 μm to 100 μm. The size of the pad 56 is the same as that of the pad 54, for example. A center-to-center distance D2 between the pad 54 and the pad 56 is, for example, 100 μm to 200 μm.

The light receiving element 100 detects the light incident on the substrate 10. The wavelength of the light to be detected is, for example, 1.55 μm, and may be 1.26 μm to 1.63 μm. The light receiving element 100 is used to receive a high-speed modulated optical signal in an optical communication system. The substrate 10 and the photodiode 30 are evanescently optically coupled. In the mesa 44 of the photodiode 30, a pin (positive-intrinsic-negative) junction is formed by the n-type semiconductor layer 32, the light-absorbing layer 34, and the p-type semiconductor layer 36. A reverse bias voltage is applied to the photodiode 30 using the pad 54 and the pad 56. The mesa 44 is depleted by the application of the voltage.

Light propagates through the waveguide 20 and transits from the waveguide 20 to the photodiode 30 at the transition structure 46. The light-absorbing layer 34 of the photodiode 30 absorbs light and generates photocarriers (hole-electron pairs). The photocarriers are output as photocurrent.

The transition structure 46 has the tapered portion 21 and the tapered portion 25, and has the protruding portion 42 of the photodiode 30. Reflection and scattering of light are less likely to occur, and loss of light is reduced.

The air gap 27 in the silicon layer 16 is surrounded by the wall 24 and the slab portion 28 in the XY plan, and is covered by the slab portion 40 of the photodiode 30 in the Z-axis direction. The air gap 27 is sealed by the wall 24, the slab portion 28 and the slab portion 40. By allowing the air gap 27 to function as an air cladding, it is possible to enhance light confinement in the light-absorbing layer 34 of the photodiode 30. By coupling light to the light-absorbing layer 34 with high efficiency, the responsivity increases.

### (Simulation)

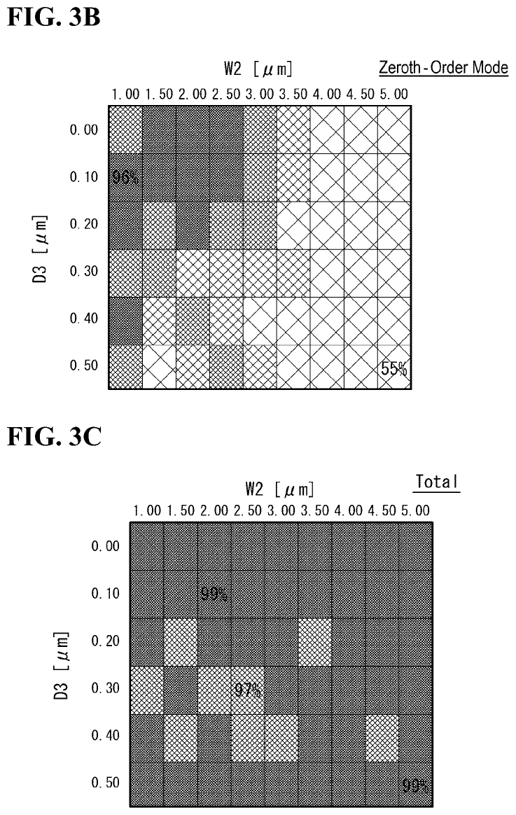

FIG. 3A is a top view illustrating parameters in a simulation, and shows the enlarged transition structure 46. The width W1 of the waveguide 20 and a width W5 of the waveguide 26 are set to 0.5 μm. A thickness T1 of the wall 24 in the X-axis direction is set to 1 μm. A length L4 of the tapered portion 21 of the silicon layer 16 is set to 60 μm. A length L5 of the tapered portion 25 is set to 9 μm. A width W6 of the distal end of the protruding portion 42 of the photodiode 30 is set to 0.2 μm. The width of the connecting portion of the protruding portion 42 with the slab portion 40 is defined as W2. A distance from an end portion of the protruding portion 42 to an end portion of the tapered portion 21 in the Y-axis direction is defined as D3. The transmittance of light from the negative X direction to the positive X direction of the wall 24 is calculated by changing the width W2 and the distance D3.

FIG. 3B and FIG. 3C are maps each illustrating the results of the simulation. The horizontal axis represents the width W2. The vertical axis represents the distance D3. The width W2 is changed from 1.0 μm to 5.0 μm in increments of 0.5 μm. The distance D3 is changed from 0.0 μm to 0.5 μm in increments of 0.1 μm. In the map, areas with a higher density of diagonal lines indicate higher transmittance.

FIG. 3B shows the transmittance of the zeroth-order mode. When the width W2 of the protruding portion 42 is large and the distance D3 is large, the transmittance decreases. In the case that the width W2 is 5.0 μm and the distance D3 is 0.5 μm, the transmittance is 55%. In the case that the width W2 of the protruding portion 42 is small and the distance D3 is small, the transmittance increases. In the case that the width W2 is 1.0 μm and the distance D3 is 0.1 μm, the transmittance is 96%.

FIG. 3C shows the transmittance (Total) of light that combines the zeroth-order mode and the higher order modes. The transmittance is 90% or more regardless of the value of the width W2 and the distance D3. In the case that the distance D3 is 0.0 μm, 0.1 μm, or 0.5 μm, the transmittance is 99% regardless of the value of the width W2. In the case that the distance D3 is 0.2 μm and the width W2 is 1.0 μm, 2.0 μm to 3.0 μm, or 4.0 μm to 5.0 μm, the transmittance is 99%. In the case that the distance D3 is 0.3 μm and the width W2 is 1.5 μm, or 3.0 μm to 5.0 μm, the transmittance is 99%. In the case that the distance D3 is 0.4 μm and the width W2 is 1.0 μm, 2.0 μm, 3.5 μm, 4.0 μm, or 5.0 μm, the transmittance is 99%. In the case of combinations of the distance D3 and the width W2 are other than those mentioned above, the transmittance is 97%. By the zeroth-order mode and the higher order modes passing through the transition structure 46 and being absorbed by the photodiode 30, the responsivity increases.

### (Method of Manufacturing)

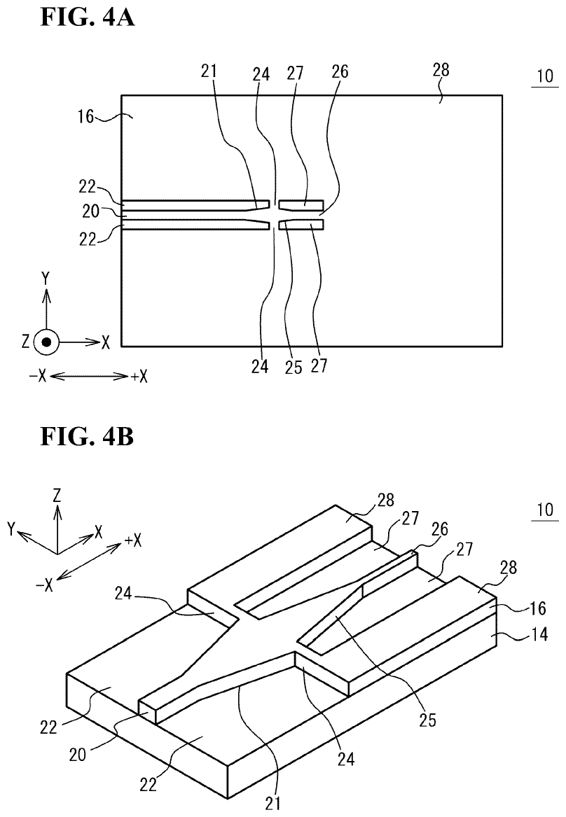

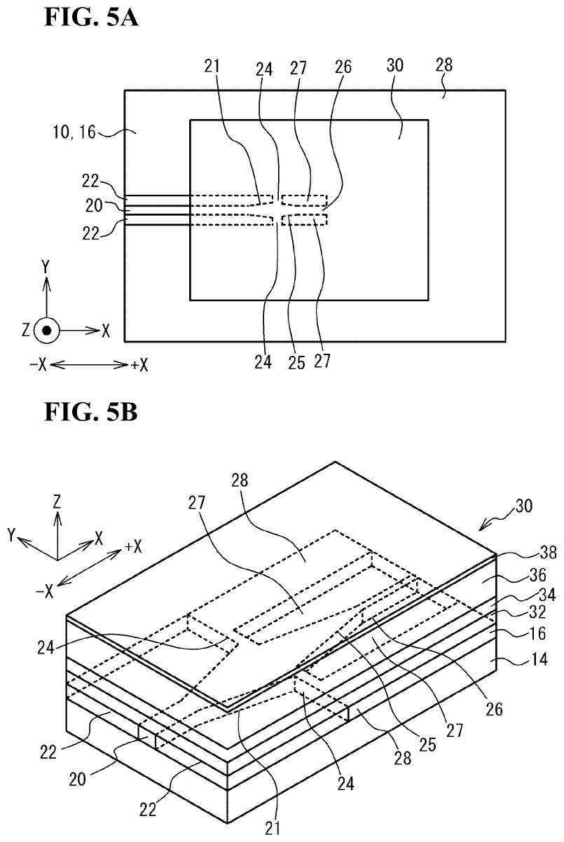

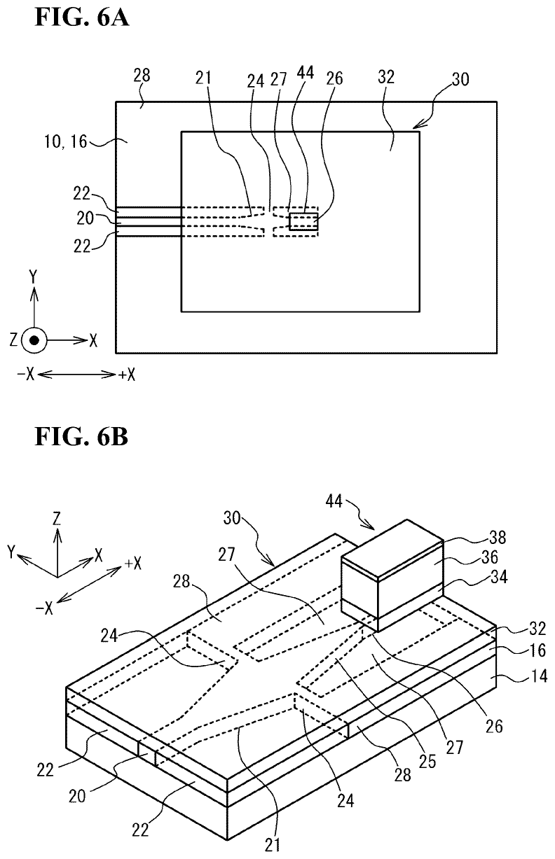

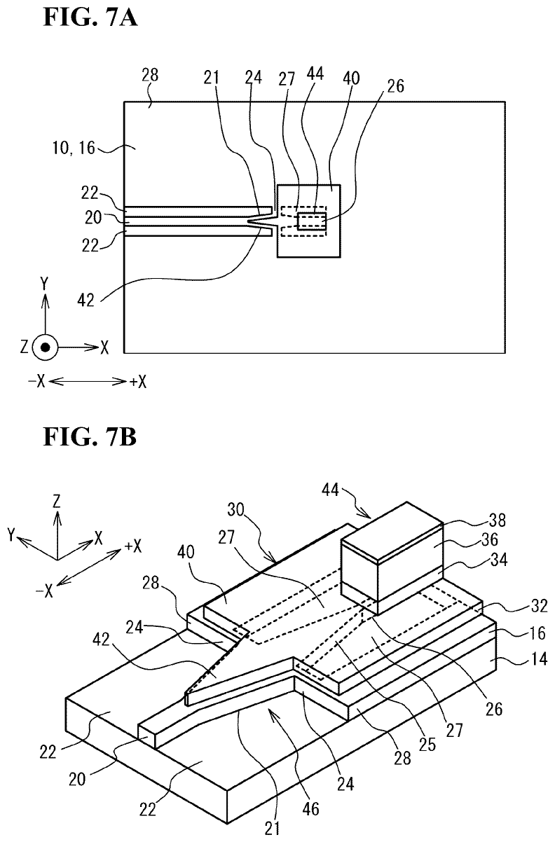

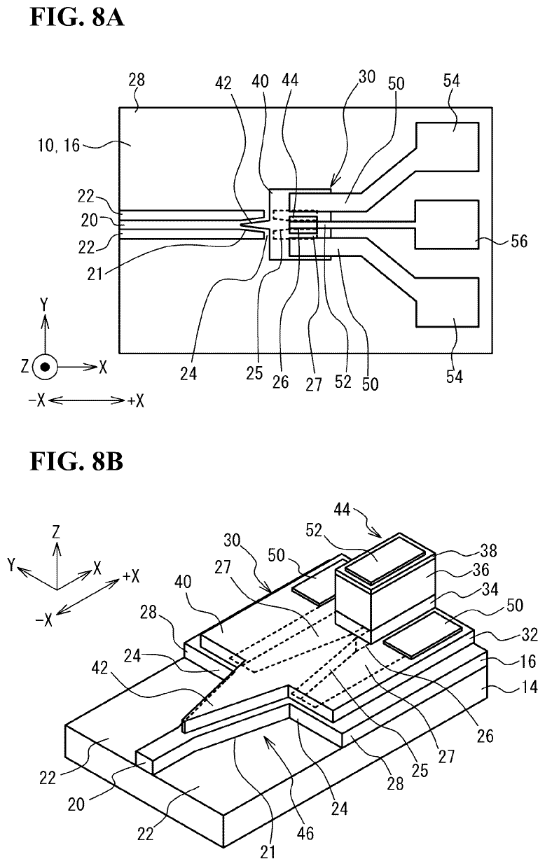

FIG. 4A, FIG. 5A, FIG. 6A, FIG. 7A and FIG. 8A are top views each illustrating a method of manufacturing the light receiving element 100. FIG. 4B, FIG. 5B, FIG. 6B, FIG. 7B and FIG. 8B are perspective views each illustrating a method of manufacturing the light receiving element 100.

As shown in FIG. 4A and FIG. 4B, for example, dry etching is performed to the silicon layer 16 of the substrate 10 (SOI substrate). The portion exposed from the mask (not shown) is etched to form the recess 22 and the air gap 27. The portion covered with the mask (not shown) is not etched. The waveguide 20, the tapered portion 21, the wall 24, the tapered portion 25, the waveguide 26, and the slab portion 28 are formed in the portion that is not etched. After the dry etching, the mask is removed.

The contact layer 38, the semiconductor layer 36, the light-absorbing layer 34, and the semiconductor layer 32 are epitaxially grown in order on an InP substrate different from the substrate 10 by metal organic chemical vapor deposition (MOCVD) or the like. Dicing is performed to the InP substrate to form the photodiode 30. The photodiode 30 immediately after dicing is a rectangular parallelepiped, and does not have the protruding portion 42 and the mesa 44.

As shown in FIG. 5A and FIG. 5B, the photodiode 30 is bonded to the upper surface of the substrate 10. In the bonding step, plasma is irradiated to one surface of the silicon layer 16 and a surface of the semiconductor layer 32 of the photodiode 30 to activate these surfaces. The surface of the semiconductor layer 32 is brought into contact with the surface of the silicon layer 16, and the photodiode 30 is bonded to the silicon layer 16. The photodiode 30 covers the upper surface of the silicon layer 16. The tapered portion 21, the wall 24, the tapered portion 25, the waveguide 26, and the air gap 27 are disposed under the photodiode 30.

After the bonding, wet etching is performed to remove the InP substrate of the photodiode 30. The layers from the semiconductor layer 32 to the contact layer 38 remain. A chemical solution is used in wet etching. The chemical solution enters the recess 22, but is blocked by the wall 24, and thus is less likely to intrude into the air gap 27. The photodiode 30 is less likely to be etched from the bonding interface side, and damage can be avoided.

As shown in FIG. 6A and FIG. 6B, the mesa 44 is formed on the photodiode 30. Portions of the contact layer 38, the semiconductor layer 36, and the light-absorbing layer 34 exposed from the mask (not shown) are removed by dry etching. The mesa 44 is formed in the portion covered with the mask. In the dry etching, for example, a chlorine-based etching gas is used. After the dry etching, the mask is removed. The semiconductor layer 32 of the photodiode 30 covers the upper surface of the substrate 10.

As shown in FIG. 7A and FIG. 7B, the slab portion 40 and the protruding portion 42 are formed in the photodiode 30. The mesa 44 and a portion of the semiconductor layer 32 are covered with a mask (not shown). A portion of the semiconductor layer 32 exposed from the mask is removed by wet etching, thereby forming the slab portion 40 and the protruding portion 42. In the wet etching, for example, a hydrochloric acid-based etchant is used. After the wet etching, the mask is removed. A chemical solution such as buffered hydrofluoric acid is used for removing the mask. The air gap 27 is sealed by the wall 24, the slab portion 28 and the slab portion 40. Thus, a liquid such as an etchant is less likely to intrude into the air gap 27. The photodiode 30 is less likely to be etched from the bonding interface side.

As shown in FIG. 8A and FIG. 8B, the electrode 50 and the electrode 52 and the pad 54 and the pad 56 are provided by vacuum evaporation and lift-off. By dividing the substrate 10, the light receiving element 100 is formed.

According to the first embodiment, the silicon layer 16 of the substrate 10 has the waveguide 20, the tapered portion 21, the recess 22, the wall 24, the tapered portion 25, the waveguide 26, the air gap 27, and the slab portion 28. The photodiode 30 is bonded to the silicon layer 16. The air gap 27 functions as an air cladding, and light is strongly confined in the photodiode 30. By strengthening the light confinement, even when the photodiode 30 is miniaturized, the responsivity can be increased. By miniaturizing the photodiode 30, the parasitic capacitance is reduced, and high-speed operation is possible. Both high responsivity and a wide bandwidth can be achieved.

The wall 24 of the silicon layer 16 is provided between the recess 22 and the air gap 27. The air gap 27 is sealed by the wall 24, the slab portion 28, and the photodiode 30. The chemical solution for wet etching is blocked by the wall 24, and thus is less likely to intrude into the air gap 27. The photodiode 30 is not etched from the bonding interface side, and damage is less likely to occur. Liquid used for cleaning is also less likely to enter the air gap 27. Damage to the photodiode 30 due to vaporization of the liquid can also be avoided.

The air gap 27 is surrounded by the wall 24 and the slab portion 28, and is covered with the slab portion 40 of the photodiode 30. The liquid intrusion can be avoided from all directions. Damage to the photodiode 30 can be effectively avoided. In wet etching for forming the protruding portion 42 or the like, other wet etchings, and processes using liquid, the liquid intrusion is avoided.

The transition structure 46 includes the tapered portion 21 of the silicon layer 16. The wall 24 is perpendicular to the X-axis direction which is the propagation direction of light, and thus is likely to reflect light. Since the tapered portion 21 is disposed between the waveguide 20 and the wall 24, light transitions gradually to the photodiode 30 in the tapered portion 21. Reflection and scattering of light can be avoided, and loss of light can be reduced. Since low-loss light transitions to the photodiode 30, the responsivity increases.

The tapered portion 25 is provided between the wall 24 of the silicon layer 16 and the waveguide 26. The cross-sectional shape gradually changes in the tapered portion 21 and the tapered portion 25. Thus, loss of light can be reduced.

The mesa 44 of the photodiode 30 includes the light-absorbing layer 34, the semiconductor layer 36, and the contact layer 38. In the Z-axis direction, the air gap 27 overlaps the mesa 44. By allowing the air gap 27 to function as an air cladding, light is strongly confined in the mesa 44 and efficiently coupled to the light-absorbing layer 34. The responsivity is improved.

The semiconductor layer 32 of the photodiode 30 has the slab portion 40 and the protruding portion 42. The slab portion 40 is bonded to the silicon layer 16. The protruding portion 42 protrudes from the slab portion 40 toward the waveguide 20 and overlaps the tapered portion 21. The protruding portion 42, the tapered portion 21, and the tapered portion 25 form the transition structure 46. The light propagated through the waveguide 20 transitions to the photodiode 30 in the transition structure 46. By enhancing the coupling efficiency, it is possible to confine light in the light-absorbing layer 34 and improve the responsivity.

The protruding portion 42 of the photodiode 30 may have a tapered shape. The widths of the tapered portion 21 and the protruding portion 42 are increased toward the photodiode 30. The light of the single mode propagates through the waveguide 20, and the higher order modes are excited in the tapered portion 21 and the protruding portion 42 and spreads over a wide range. Since the light intensity is not localized, the photocarrier is also not localized. High responsiveness can be achieved even for high-frequency optical signals.

As shown in FIG. 3A to FIG. 3C, the transmittance of the zeroth-order mode and the higher order modes can be increased to 90% or more by adjusting the dimensions. The photodiode 30 absorbs both the transmitted zeroth-order mode and the higher order modes.

A central portion of the mesa 44 of the photodiode 30 in the Y-axis direction overlaps the waveguide 26 of the silicon layer 16 and is supported by the waveguide 26. The mechanical strength of the light receiving element 100 is improved. The air gaps 27 are provided on both sides of the waveguide 26 and overlap the mesa 44 when viewed from the Z-axis direction through the semiconductor layer 32.

Since the air gap 27 functions as an air cladding, the responsivity can be increased. The tapered portion 21, the tapered portion 25, and the waveguide 26 do not have to be provided in the silicon layer 16. The photodiode 30 do not have to be provided with the protruding portion 42.

### Second Embodiment

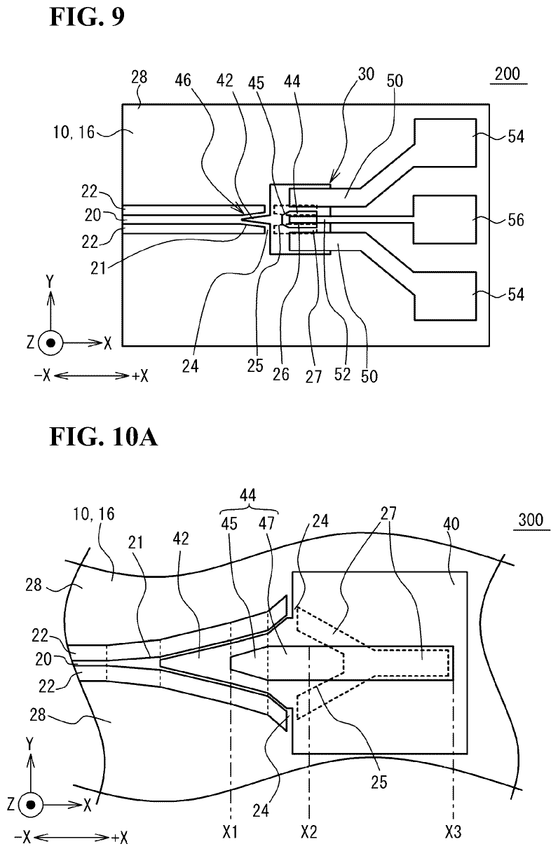

FIG. 9 is a plan view illustrating a light receiving element 200 according to a second embodiment. The description of the same configuration as that of the first embodiment will be omitted. A mesa 44 has a tapered portion 45 (third tapered portion). The tapered portion 45 is disposed at the distal end of the mesa 44 in the negative X direction. The width of the tapered portion 45 is smaller closer to the waveguide 20, and is larger farther from the waveguide 20.

According to the second embodiment, an air gap 27 functions as an air cladding, and thus it is possible to strengthen the light confinement to a photodiode 30. Since the mesa 44 has the tapered portion 45, the coupling efficiency is increased, allowing for further reduction in loss of light. A wall 24 can block the chemical solution. Since the chemical solution is less likely to enter the air gap 27, etching of the photodiode 30 on the bonding interface side can be avoided.

### Third Embodiment

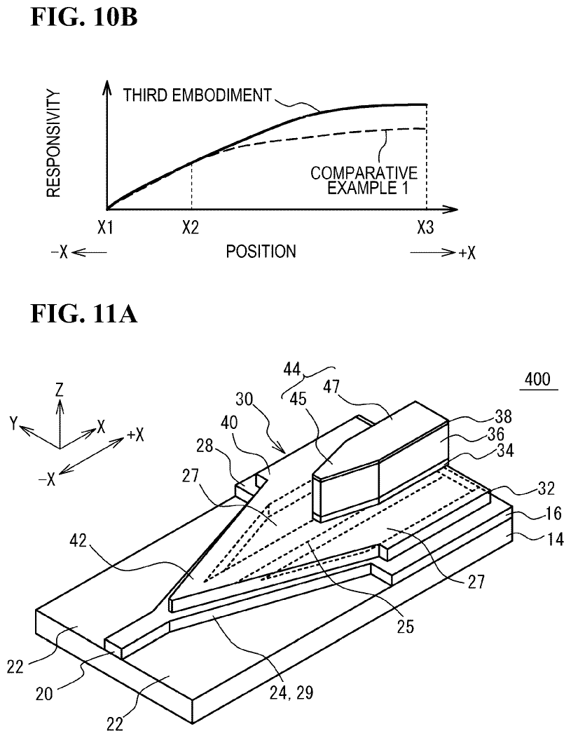

FIG. 10A is a top view illustrating a light receiving element 300 according to a third embodiment, and shows a portion including a mesa 44 in an enlarged manner. The description of the same configuration as that of the first embodiment or the second embodiment will be omitted.

As shown in FIG. 10A, a transition structure 46 has a kite shape. The width of a tapered portion 21 of a silicon layer 16 gradually increases toward a slab portion 40 of a photodiode 30. In other words, the inclination angle of the tapered portion 21 from an X-axis direction gradually increases. A recess 22 is inclined from the X-axis direction corresponding to the tapered portion 21. In FIG. 10A, the positions where the angle of the tapered portion 21 changes are indicated by dotted lines.

The silicon layer 16 has a tapered portion 25 and an air gap 27 from a wall 24 in the positive X direction, but does not have a waveguide 26. The air gap 27 has a Y-shape in the plan view. The air gaps 27 are provided on both sides of the tapered portion 25, and have a linear shape parallel to the tapered portion 25 in the positive X direction.

The tapered portion 45 is provided at a distal end of the mesa 44 of the photodiode 30 in the negative X direction. A portion of the mesa 44 with respect to the tapered portion 45 in the positive X direction is referred to as a linear portion 47. The linear portion 47 is parallel to the X-axis direction. The mesa 44 protrudes from a position overlapping the slab portion 40 to a position above the protruding portion 42. The tapered portion 45 of the mesa 44 is disposed above the tapered portion 21 of the silicon layer 16 and the protruding portion 42 of the photodiode 30. A portion of the linear portion 47 of the mesa 44 connected to the tapered portion 45 is disposed above the tapered portion 21 and the protruding portion 42. The linear portion 47 extends from the protruding portion 42 to a region above the slab portion 40 and the air gap 27. The mesa 44 is supported by the tapered portion 21 and the tapered portion 25 of the silicon layer 16, and is supported by a portion of a slab portion 28 that is in contact with the air gap 27.

The distal end of the mesa 44 in the negative X direction is defined as a position X1. The partway of the tapered portion 25 of the mesa 44 is defined as a position X2. The distal end of the mesa 44 in the positive X direction is defined as a position X3.

FIG. 10B is a diagram illustrating the responsivity. The horizontal axis represents the position in the X-axis direction in the mesa 44. The left direction of the horizontal axis is the negative X direction. The right direction is the positive X direction. The vertical axis represents the responsivity. The solid line represents the third embodiment. The dashed line represents comparative example 1. In comparative example 1, the silicon layer 16 does not have the wall 24 and the air gap 27. The slab portion 28 of the silicon layer 16 is disposed under the photodiode 30. The other configurations are the same as those of the third embodiment.

The light propagates through a waveguide 20 from the negative X direction to the positive X direction, transitions to the photodiode 30, and is absorbed by a light-absorbing layer 34. The responsivity increases from the negative X direction toward the positive X direction. The responsivity is lowest at the position X1 of the distal end of the mesa 44 in the negative X direction. From the position X1 to the position X2, the responsivity of the third embodiment and the responsivity of comparative example 1 are approximately the same. The difference between the responsivity of the third embodiment and the responsivity of comparative example 1 increases from the position X2 toward the position X3. Since no air cladding is provided in comparative example 1, the confinement of light is weak, and the loss of light increases in the slab portion 28. The responsivity is lowered.

According to the third embodiment, the mesa 44 of the photodiode 30 protrudes above the protruding portion 42 and extends in the negative X direction from the wall 24. Since the mesa 44 protrudes from the wall 24, light transitions to and is absorbed by the mesa 44 before any loss of light occurs due to the wall 24. The influence of the wall 24 on the light-absorbing is reduced. The air gap 27 is provided in the positive X direction with respect to the wall 24, and light is confined in the mesa 44. By allowing the light-absorbing layer 34 to absorb light efficiently, the responsivity increases.

As shown in FIG. 10A, the linear portion 47 of the mesa 44 is disposed above and supported by the slab portion 28. The mechanical strength is improved.

### Fourth Embodiment

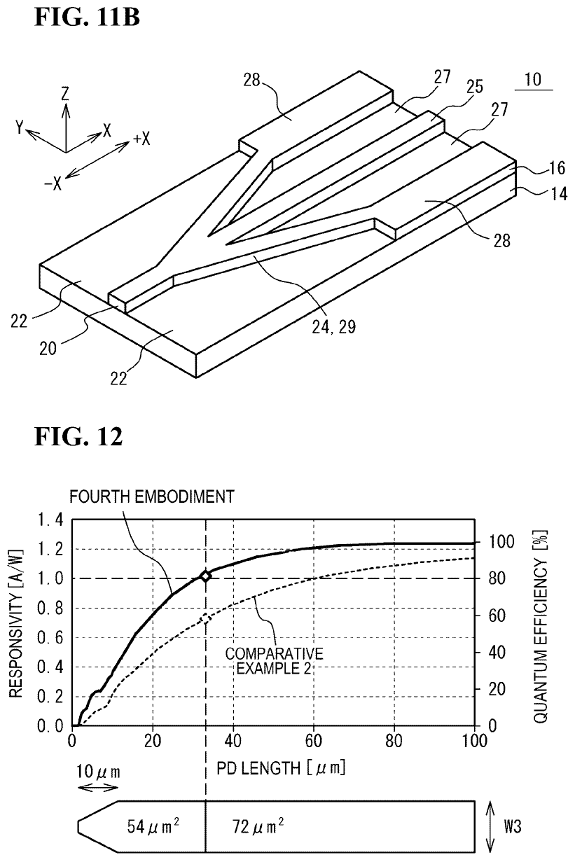

FIG. 11A is a perspective view illustrating a light receiving element 400 according to a fourth embodiment. FIG. 11B is a perspective view illustrating a substrate 10. The description of the same configuration as that of any of the first embodiment to the third embodiment will be omitted. Although not shown, the light receiving element 400 has electrodes similar to those in FIG. 1A. A transition structure 46 has a dart shape.

As shown in FIG. 11A and FIG. 11B, a wall 24 of a silicon layer 16 includes a tapered shape, where, for example, the entire wall 24 is a tapered portion 29 (first tapered portion). The width of the tapered portion 29 is narrower farther from the photodiode 30 and is wider closer to a photodiode 30. The tapered portion 29 is connected to a slab portion 28. A waveguide 20 is connected to the distal end of the tapered portion 29. A waveguide 26 is connected to the inner wall of the tapered portion 29. Air gaps 27 are provided on both sides of the waveguide 26. A protruding portion 42 of the photodiode 30 overlaps the tapered portion 29.

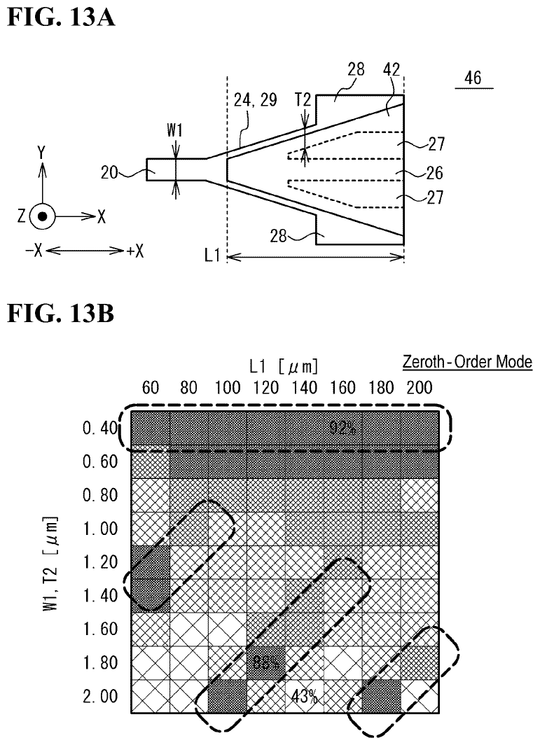

FIG. 12 is a diagram illustrating calculation results of the responsivity and the quantum efficiency. The left vertical axis represents the responsivity. The right vertical axis represents the quantum efficiency. The horizontal axis represents the length of a mesa 44 in an X-axis direction. The length ranges are from 0 μm to 100 μm. A tapered portion 45 of the mesa 44 has a length of 10 μm. In the case that the length of the mesa 44 is 10 μm or more, a linear portion 47 is connected to the tapered portion 45 in the positive X direction having a length of 10 μm. The width W3 of the mesa 44 is 2 μm. In the dashed line in FIG. 12, the length of mesa 44 is between 30 μm and 40 μm, and the area of the upper surface of mesa 44 is 54 μm². In the case that the length of the mesa 44 is 60 μm, the area is 72 μm². In order to obtain the 3 dB bandwidth to 60 GHz, the area may be set to, for example, 54 μm² or less.

In FIG. 12, the solid line represents the fourth embodiment. The dotted line represents comparative example 2. Comparative example 2 does not have the wall 24 or the air gap 27. The other configurations are the same as those of the fourth embodiment. The longer the mesa 44 is, the more the responsivity and the quantum efficiency are improved. The responsivity and quantum efficiency of the fourth embodiment are higher compared to those of comparative example 2. In the length indicated by the dashed line, the responsivity of comparative example 2 is about 0.7 A/W, and the quantum efficiency is about 60%. The responsivity of the fourth embodiment is 1.0 A/W, and the quantum efficiency is 80%. In order to achieve the responsivity of 1.0 A/W and the quantum efficiency of 80% in comparative example 2, the length of the mesa 44 may be set to 60 μm. However, since the area of the mesa 44 becomes 72 μm², the capacitance increases, making high-speed operation difficult. In the fourth embodiment, in the case that the responsivity is 1.0 A/W and the quantum efficiency is 80%, the area of the mesa 44 is 54 μm². Since the capacitance decreases, high-speed operation is possible. That is, both high responsivity and high-speed operation can be achieved.

### (Simulation)

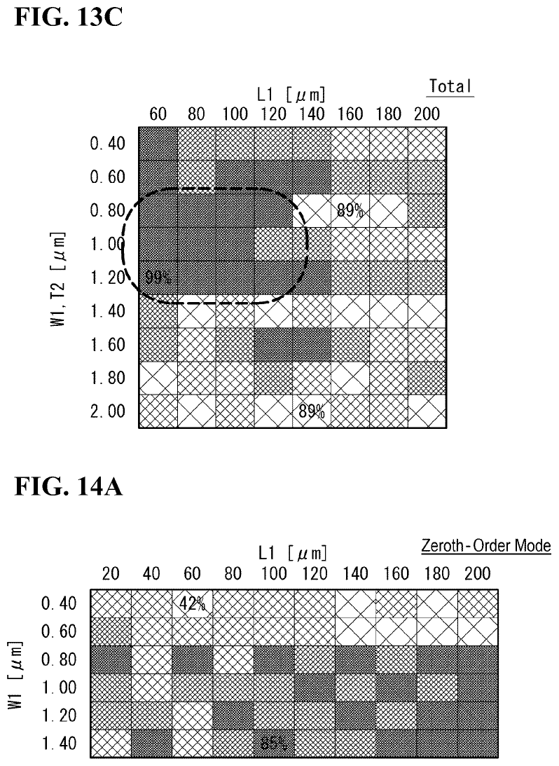

FIG. 13A is a top view illustrating parameters in the simulation, and shows the enlarged transition structure 46. A width W1 of the waveguide 20, a thickness T2 of the wall 24 in a Y-axis direction, and a length L1 of the protruding portion 42 of the photodiode 30 are parameters.

FIG. 13B and FIG. 13C are maps each illustrating the results of the simulation. The horizontal axis represents the length L1. The vertical axis represents the width W1 and the thickness T2. In the examples of FIG. 13B and FIG. 13C, the length L1 is changed from 60 μm to 200 μm in increments of 20 μm. The width W1 is changed from 0.4 μm to 2.0 μm in increments of 0.2 μm. The thickness T2 of the wall 24 is changed in the similar manner as the width W1 of the waveguide 20, and is set to a value equal to the width W1. In FIG. 13B and FIG. 13C, the high transmittance portion is surrounded by a dashed line.

FIG. 13B shows the transmittance of the zeroth-order mode. In the case that the width W1 and the thickness T2 are 0.4 μm, the transmittance is 90% or more, for example 92%, regardless of the value of the length L1. When the width W1 and the thickness T2 are set to be larger than 0.4 μm and the length L1 is changed, the transmittance is periodically improved. For example, in the case that the width W1 and the thickness T2 are 1.8 μm and the length L1 is 120 μm, the transmittance is 88%. In the case that the width W1 and the thickness T2 are 2.0 μm and the length L1 is either 100 μm or 180 μm, the transmittance becomes high. In the case that the width W1 and the thickness T2 are 1.2 μm to 1.4 μm, and the length L1 is 60 μm, the transmittance becomes high.

FIG. 13C shows the transmittance of light that combines the zeroth-order mode and the higher order modes. In the case that the width W1 and the thickness T2 are 1.2 μm or less and the length L1 are 120 μm or less, the transmittance becomes high. In the case that the width W1 and the thickness T2 are 120 μm and the length L1 is 60 μm, the transmittance is 99%.

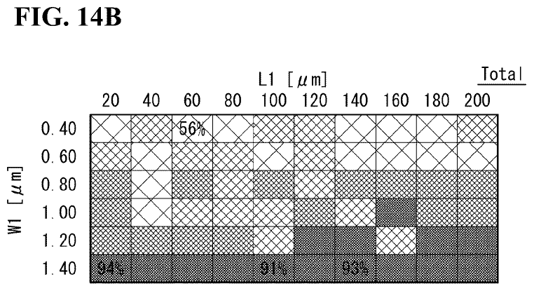

FIG. 14A and FIG. 14B are maps each illustrating the results of the simulation. In the example of FIG. 14A and FIG. 14B, the thickness T2 of the wall 24 is fixed to 1 μm.

FIG. 14A shows the transmittance of the zeroth-order mode. FIG. 14B shows the transmittance of light that combines the zeroth-order mode and the higher order modes. In FIG. 14A and FIG. 14B, the transmittance becomes higher for the wider width W1 of the waveguide 20 compared to the narrower width W1. The thicker the wall 24 is relative to the waveguide 2, the loss of light increases. The thinner the wall 24 is relative to the waveguide 20, the lower the loss of light and the higher the transmittance. In the example of FIG. 14A, in the case that the width W1 is 1.4 μm and the length L1 is 100 μm, the transmittance is 85%. When the width W1 is 0.8 μm or more and the length L1 is 180 μm or more, the transmittance is high. In the example of FIG. 14B, when the width W1 is 1.4 μm, the transmittance is 90% or more regardless of the value of the length L1.

According to the fourth embodiment, the air gap 27 functions as an air cladding, and thus it is possible to strengthen the light confinement to the photodiode 30. Since the wall 24 has a tapered shape, the loss of light is reduced. The responsivity can be increased. The wall 24 can block the chemical solution. Since the chemical solution is less likely to enter the air gap 27, etching of the photodiode 30 on the bonding interface side can be avoided.

Although the embodiments of the present disclosure have been described in detail, the present disclosure is not limited to the specific embodiments, and various modifications and changes can be made within the scope of the gist of the present disclosure described in the claims.

What is claimed is:

1. A light receiving element comprising:
a substrate having a silicon layer; and
a photodiode formed of a III-V compound semiconductor and bonded to the silicon layer, wherein
the silicon layer includes a waveguide, a recess, an air gap, and a wall,
the wall is provided between the recess and the air gap,
the waveguide is connected to the wall,
the waveguide and the recess are provided outside the photodiode, and
the air gap is provided at a position overlapping the photodiode.

2. The light receiving element according to claim 1, wherein
the silicon layer includes a first tapered portion,
a width of the first tapered portion is larger closer to the photodiode and smaller farther from the photodiode, and
the waveguide is connected to the first tapered portion.

3. The light receiving element according to claim 2, wherein
the first tapered portion is disposed between the wall and the waveguide and is connected to the wall and the waveguide.

4. The light receiving element according to claim 3, wherein
the silicon layer has a second tapered portion,
the second tapered portion is connected to the wall and overlaps the photodiode, and
a width of the second tapered portion is larger closer to the wall and smaller farther from the wall.

5. The light receiving element according to claim 2, wherein
the wall includes the first tapered portion.

6. The light receiving element according to claim 1, wherein
the silicon layer has a first slab portion,
the photodiode is bonded to the first slab portion,
the wall is connected to the first slab portion, and
the air gap is surrounded by the wall and the first slab portion.

7. The light receiving element according to claim 1, wherein
the photodiode includes a first semiconductor layer, a light-absorbing layer, and a second semiconductor layer,
the first semiconductor layer has a first conductivity type,
the second semiconductor layer has a second conductivity type,
the first semiconductor layer is bonded to the silicon layer,
the light-absorbing layer and the second semiconductor layer are stacked on the first semiconductor layer in this order to form a mesa, and
the air gap is provided at a position overlapping the mesa.

8. The light receiving element according to claim 7, wherein
the first semiconductor layer includes a second slab portion and a protruding portion,
the protruding portion is connected to the second slab portion and protrudes from the second slab portion toward the waveguide,
the mesa protrudes from the second slab portion in a direction opposite to the silicon layer, and
the air gap is provided at a position overlapping the mesa and the second slab portion.

9. The light receiving element according to claim 8, wherein
the mesa extends from a position overlapping the second slab portion to a position overlapping the protruding portion.

10. The light receiving element according to claim 7, wherein
the mesa has a third tapered portion, and
the third tapered portion has a shape tapering along an extending direction of the waveguide.

11. The light receiving element according to claim 7, wherein
a portion of the mesa overlaps the silicon layer and is supported by the silicon layer.

12. A method of manufacturing a light receiving element including a substrate having a silicon layer, and a photodiode formed of a III-V compound semiconductor,
wherein the silicon layer includes a waveguide, a recess, an air gap, and a wall,
the wall is provided between the recess and the air gap, and
the waveguide is connected to the wall, and
wherein the method comprises:
bonding the photodiode to the silicon layer; and
performing a wet etching on the photodiode, and
wherein, after the performing of the wet etching, the waveguide and the recess are provided outside the photodiode, and the air gap is provided at a position overlapping the photodiode.
